(19) United States
(12) Patent Application Publication
(10) Pub. No.: US 2011/0312148 A1
(43) Pub. Date: Dec. 22, 2011

(54) CHEMICAL VAPOR DEPOSITION OF RUTHENIUM FILMS CONTAINING OXYGEN OR CARBON

(75) Inventors: HOON KIM, San Jose, CA (US); SANG-HYEOB LEE, Fremont, CA (US); SANG HO YU, Cupertino, CA (US); WEI TI LEE, San Jose, CA (US); SESHADRI GANGULI, Sunnyvale, CA (US); HYOUNG-CHAN HA, San Jose, CA (US)

(73) Assignee: APPLIED MATERIALS, INC., Santa Clara, CA (US)

(21) Appl. No.: 13/155,520

(22) Filed: Jun. 8, 2011

Related U.S. Application Data
(60) Provisional application No. 61/356,391, filed on Jun. 18, 2010.

(51) Int. Cl. H01L 21/02; B82Y 40/00

(52) U.S. Cl. 438/381; 977/890; 257/E21.008

(57) ABSTRACT

Methods for depositing ruthenium-containing films are provided herein. In some embodiments, a method of depositing a ruthenium-containing film on a substrate may include depositing a ruthenium-containing film on a substrate using a ruthenium-containing precursor, the deposited ruthenium-containing film having carbon incorporated therein; and exposing the deposited ruthenium-containing film to an oxygen-containing gas to remove at least some of the carbon from the deposited ruthenium-containing film. In some embodiments, the oxygen-containing gas exposed ruthenium-containing film may be annealed in a hydrogen-containing gas to remove at least some oxygen from the ruthenium-containing film. In some embodiments, the deposition, exposure, and annealing may be repeated to deposit the ruthenium-containing film to a desired thickness.

### CROSS-REFERENCE TO RELATED APPLICATIONS

This application claims benefit of U.S. provisional patent application Ser. No. 61/356,391, filed Jun. 18, 2011, which is herein incorporated by reference.

### FIELD

Embodiments of the present invention generally relate to semiconductor devices and methods of fabrication thereof.

### BACKGROUND

As the feature size of dynamic random access memory (DRAM) devices is decreased, a higher capacitance density is required. Unfortunately, conventional capacitor designs, such as those having titanium nitride (TiN)/high-k dielectric material/titanium nitride (TiN) (TIT) structure cannot meet the requirement of effective oxide thickness (EOT) for the next generation (e.g., <45 nm) due to high leakage caused by the low work function of the metal electrode (TiN).

Ruthenium (Ru) is a candidate element for inclusion in the electrodes of a capacitor to achieve the EOT requirement of about 5 angstroms due to its high work function and low reactivity with high-k materials. For example, such high-k dielectric materials may have a dielectric constant of about 100 or more.

Unfortunately, the deposition of Ru is challenging. For example, the deposition may include such limitations as low deposition rate, poor step coverage, high resistivity, and poor adhesion to oxides. Although some Ru deposition techniques have been reported that satisfy some of these requirements, no satisfactory process has yet been developed that satisfies all of the requirements. For example, chemical vapor deposition (CVD) with triruthenium dodecacarbonyl (Ru₃(CO)₁₂) has shown good layer resistivity, but the adhesion, deposition rate, and step coverage were all poor and thus inadequate for device applications

Accordingly, the inventors have provided improved methods for depositing ruthenium-containing films.

### SUMMARY

Methods for depositing ruthenium-containing films are provided herein. In some embodiments a method of depositing a ruthenium film may include depositing a ruthenium film on a substrate via a chemical vapor deposition process using a metalorganic ruthenium precursor, the deposited ruthenium film having carbon incorporated therein; and exposing the deposited ruthenium film to oxygen to remove at least some of the carbon from the ruthenium film. In some embodiments, the deposition of the ruthenium film and the subsequent exposure to oxygen may be repeated. In some embodiments, the oxygen-exposed ruthenium film may be thermally annealed.

In some embodiments, a method of depositing a ruthenium-containing layer on a substrate may include depositing a ruthenium-containing film on a substrate using a ruthenium-containing precursor, the deposited ruthenium-containing film having carbon incorporated therein; and exposing the deposited ruthenium-containing layer to an oxygen-containing gas to remove at least some of the carbon from the deposited ruthenium-containing film. In some embodiments, the oxygen-containing gas exposed ruthenium-containing film may be annealed in a hydrogen-containing gas to remove at least some oxygen from the ruthenium-containing film. In some embodiments, the deposition, exposure, and annealing may be repeated to deposit the ruthenium-containing film to a desired thickness.

In some embodiments, an oxide layer may be deposited atop the ruthenium-containing film and a second ruthenium-containing film may be deposited atop the oxide layer. In some embodiments, the second ruthenium-containing film may be deposited and processed by a substantially similar method as the ruthenium-containing film. In some embodiments, the ruthenium-containing film, the second ruthenium-containing film, and the oxide layer form a capacitor, for example, that may be coupled to one of a source or drain of a transistor device via the substrate.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart of a method for depositing a ruthenium-containing layer in accordance with some embodiments of the present invention.

FIGS. 2A-C depict the stages of depositing a ruthenium-containing film in accordance with some embodiments of the present invention.

FIG. 3 depicts a flow chart for a method for fabricating a multi-layer structure having one or more ruthenium-containing films in accordance with some embodiments of the present invention.

FIGS. 4A-D depict the stages of fabrication for a multi-layer structure having one or more ruthenium-containing films in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods for depositing ruthenium-containing films are disclosed herein. The inventive methods may advantageously allow for a ruthenium-containing film to be deposited having any or all of adequate resistivity, adhesion, deposition rate, or step coverage for device applications. Exemplary device applications may include capacitors having one or more ruthenium-containing film formed by the inventive methods disclosed herein. In some embodiments, the exemplary capacitors may be part of a larger device such as a dynamic random access memory (DRAM) cell.

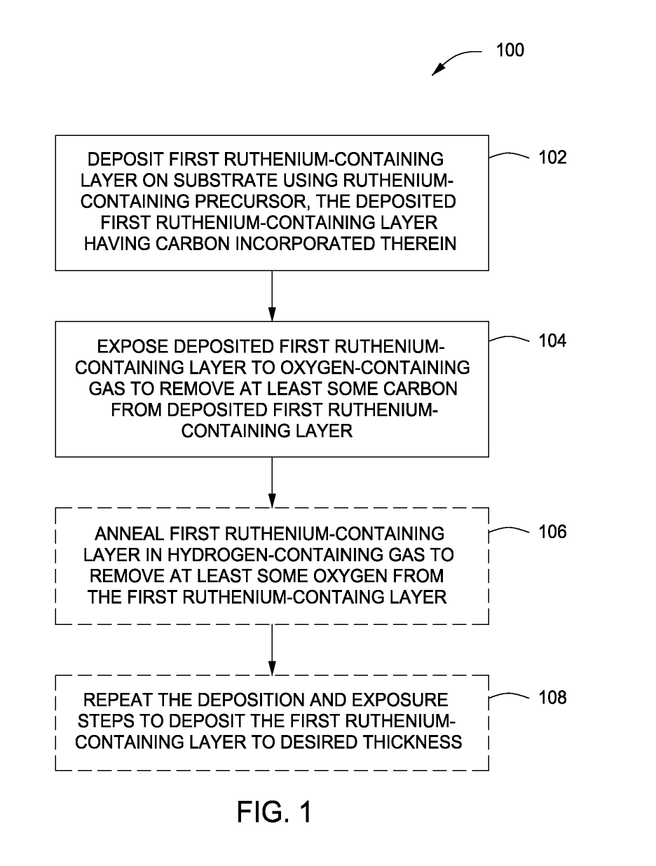

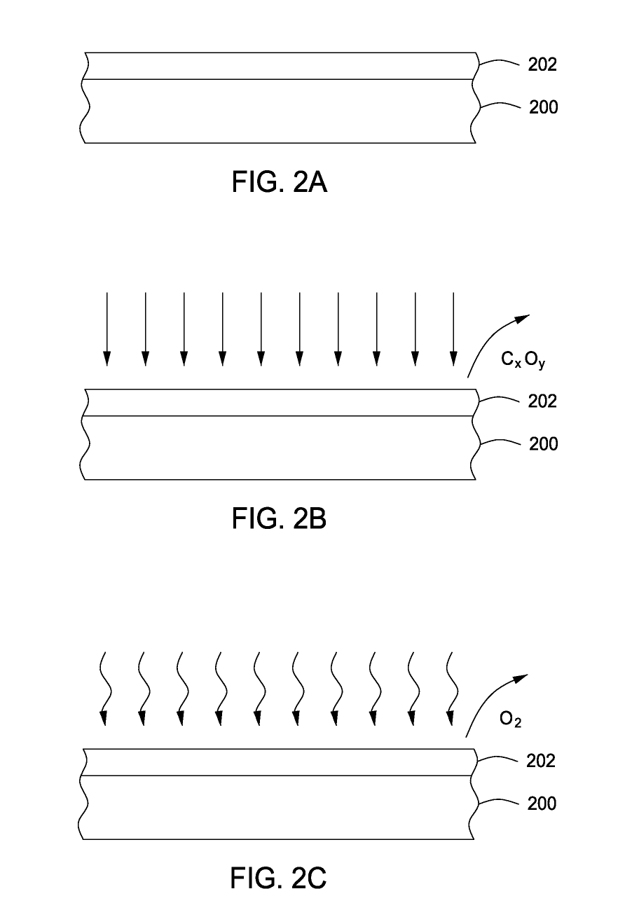

FIG. 1 depicts a flow chart for a method 100 for depositing a ruthenium-containing film in accordance with some embodiments of the present invention. The method 100 is described below with respect to the stages of fabrication of a first ruthenium-containing film 202 as depicted in FIGS. 2A-C. The deposition of a ruthenium-containing film form by any of the methods disclosed herein may be performed in a process chamber configured for chemical vapor deposition (CVD). The CVD chamber may be any suitable CVD chamber known in the art. For example, the CVD chamber may be a standalone process chamber or a part of a cluster tool, such as one of the CENTURA®, PRODUCER®, or ENDURA® cluster tools available from Applied Materials, Inc. of Santa Clara, Calif.

The method 100 begins at 102 where a first ruthenium-containing film 202 may be deposited on a substrate 200 as illustrated in FIG. 2A. The first ruthenium-containing film 202 may include carbon (C) incorporated therein as initially deposited. For example, the first ruthenium-containing film 202 may include about 20 atomic percent C, or ranging from about 2 atomic percent to about 30 atomic percent C. The high carbon content in the initially deposited ruthenium-containing film 202 may result in a layer having an amorphous morphology. Further, the high carbon content may result in a layer having a smooth surface and/or uniform thickness. The high carbon content in the initially deposited first ruthenium-containing film 202 may be due to carbon-containing precursor in combination with a high deposition rate of about 60 Angstroms/minute or greater, or ranging from about 20 to about 100 Angstroms/minute. The initially deposited first ruthenium-containing film 202 may have a high resistivity due to the high carbon content. In some embodiments, the resistivity in the initially deposited first ruthenium-containing film 202 may range from about 150 to about 200 micro-ohm-centimeters (μΩ-cm). The initially deposited first ruthenium-containing film 202 may have good step coverage, for example, in a trench, via or other high aspect ratio structure. In some embodiments, the step coverage may be about 95% or greater, or ranging from about 60 to about_99 percent.

Chemical precursors that may be used to deposit the first ruthenium-containing film 202 as described above may include metalorganic precursors. In some embodiments, the precursor may include: dimethyl-butadienyl-ruthenium, cyclohexadine-Ru-tricarbonyl (C₆H₈—Ru(CO)₃), butadiene-Ru-tricarbonyl (C₄H₆—Ru(CO)₃), dimethylbutadiene-Ru-tricarbonyl ((CH₃)₂—C₄H₄—Ru—CO)₃), or modified dienes with ruthenium tricarbonyl (Ru(CO)₃). Each precursor may have a liquid form and may be provided in a bubbler through which a carrier gas is flowed to carry the precursor into the process chamber. The carrier gas may be any compatible inert gas, such as nitrogen or a noble gas, such as argon, helium, or the like. The carrier gas may be provided at about 100 to about 1000 sccm, or from about 300 to about 700 sccm. The quantity of the precursor delivered to the chamber may range from about 1 to about 50 sccm.

During deposition of the first ruthenium-containing film 202 at 102, the temperature inside the chamber, or of the substrate, may range from about 150 to about 300 degrees Celsius, or from about 200 to about 250 degrees Celsius. The pressure in the chamber may range from about 3 to about 10 Torr, or from about 1 to about 30 Torr. The deposition process at 102 may be carried out for a first period of time suitable to provide a desired thickness of the first ruthenium-containing film 202 prior to proceeding to process the first ruthenium-containing film 202 as discussed below to reduce carbon content at 104 or reduce oxygen content at 106. In some embodiments, the first ruthenium-containing film 202 may be deposited to a desired thickness ranging from about 5 to about 50 Angstroms at 102. Alternatively, as discussed below at 108, the first ruthenium-containing film 202 may be deposited to a desired thickness by sequentially repeating the method 100, for example, repeating steps 102 and 104, or repeating steps 102, 104 and 106 until a desired thickness of the first ruthenium-containing film 202 is achieved.

The substrate may comprise any suitable material, such as a semiconducting material and/or combinations of semiconducting materials for forming a semiconductor structure. For example, the substrate may comprise one or more silicon-containing materials such as crystalline silicon (e.g., Si<100> or Si<111>), silicon oxide (SiO₂), strained silicon, doped or undoped polysilicon, doped or undoped silicon wafers, patterned or non-patterned wafers, doped silicon, and/or other materials, such as silicon nitride (Si₃N₄), strontium titanium oxide (SrTiO3), titanium (Ti), titanium nitride (TiN) or combinations thereof. In some embodiments, the upper surface of the substrate includes an oxide or a nitride. For example, the oxide or nitride may serve as a barrier layer or the like to prevent one or more materials from the deposition of the first ruthenium-containing film 202 at 102 or subsequent processing steps of the method 100 from penetrating deeper into the substrate 200. For example, in some embodiments, the oxide or nitride may serve as a barrier layer to oxidation, such as from an oxygen-containing gas used to reduce carbon content in the first ruthenium-containing film 202 as discussed below at 104.

At 104, the deposited ruthenium-containing film 202 may be exposed to an oxygen-containing gas to remove at least some carbon (C) from the deposited first ruthenium-containing film 202 as depicted in FIG. 2B. Exposure to the oxygen-containing gas may advantageously remove C from the deposited ruthenium-containing film 202 as well as improve crystallinity of the ruthenium-containing film 202 without substantially degrading surface morphology and/or thickness uniformity of the deposited ruthenium-containing film 202. For example, as illustrated in FIG. 2B, the oxygen-containing gas may interact with carbon in the deposited ruthenium-containing film 202 to form an exhaustible effluent, such as a CₓO_{y}, where x and y are integers. Exemplary exhaustible effluents may include carbon monoxide (CO), carbon dioxide (CO₂), HCOₓ, or water vapor (H₂O).

The deposited ruthenium-containing film 202 may be exposed to the oxygen-containing gas in the same CVD chamber as used for depositing the ruthenium-containing film 202, or alternatively, in a different chamber configured for providing the oxygen-containing gas, such as an oxidation chamber or the like. The oxygen-containing gas may be provided in a range of about 500 to about 1000 sccm. The ruthenium-containing film 202 may be exposed to the oxygen-containing gas for a second period of time. The duration of the second period of time may be dependent upon the thickness of the ruthenium-containing film 202 deposited at 102. In some embodiments, the second period of time may range from about 5 to about 60 seconds. The ruthenium-containing film 202 may be exposed to the oxygen-containing gas at the same pressure and temperature as disclosed above at 102 for depositing the ruthenium-containing film 202. The oxygen-containing gas may include one or more of oxygen (O₂), water vapor (H₂O), or hydrogen peroxide (H₂O₂). In some embodiments, the oxygen-containing gas may be O₂.

The exposure to the oxygen-containing gas at 104 may result in incorporation of oxygen into the deposited ruthenium-containing film 202 in addition to the removal of carbon from the layer 202. The oxygen content in the deposited ruthenium-containing film 202 after exposure to the oxygen-containing gas at 104 may range from about 1 to about 15 atomic percent, or in some embodiments, about 5 to 10 atomic percent. In some embodiments, the oxygen content may be at least about 8 atomic percent. The removal of carbon from and/or incorporation of oxygen into the deposited ruthenium-containing film 202 may be most effective when the ruthenium-containing film 202 is thin. For example, and in some embodiments, “thin” may include a layer thickness ranging from about 10 to about 50 Angstroms.

Further, the oxygen content can be changed depending on the length of exposure time (e.g., the second period of time) to the oxygen-containing gas. For example, if lower resistivity and higher throughput is desired, the second period of time may be between about 5 to about 60 seconds. The oxygen content in the deposited ruthenium-containing film 202 may advantageously contributes to the adhesion of the ruthenium-containing film 202 on a surface of the substrate 202 surface of the substrate, for example, comprised of at least one of SiO₂ or Si₃N₄. In some embodiments, at completion of 104, the resistively of deposited ruthenium-containing film 202 has been reduced to about 60 μOhm-cm or less.

Optionally, at 106 and depicted in FIG. 2C, the first ruthenium-containing film 202 may be annealed in a hydrogen-containing gas to remove at least some oxygen from the layer 202. As discussed above for other processes, the annealing at 106 may be performed in the same CVD chamber as the deposition at 102, or alternatively, in a separate chamber configured for annealing, such as a thermal oxidation chamber, rapid thermal process (RTP) chamber, a degas chamber, or the like. The substrate 200 may be heated at 106. For example, in some embodiments, the substrate temperature may range from about 200 to about 400 degrees Celsius. In some embodiments, the pressure in the process chamber may be about 2 to about 30 Torr during annealing. The anneal at 106 may be carried out for a third period of time, for example, suitable to remove a desired amount of oxygen from the ruthenium-containing film 202. In some embodiments, the third period of time may range from about 1 to about 10 minutes.

The hydrogen-containing gas may include one or more of hydrogen (H₂), HCOOH, a hydrogen (H) radical, or a hydrogen (H₂) plasma. In some embodiments, the hydrogen-containing gas may be H₂. The removal of oxygen from the ruthenium-containing film 202 at 106 may further improve resistivity in the layer. For example, in some embodiments, after removing the oxygen, the resistivity of the ruthenium-containing film 202 may be further reduced to about 30 μOhm-cm or less.

As discussed above, the method 100 may be performed in any of several combinations of the processes discussed above. For example, the layer 202 may be deposited to the desired thickness at 102, and then exposed to the oxygen-containing gas, and then, optionally, exposed to the hydrogen-containing gas at 106. Alternatively, at 108, one or more processes at 102, 104, and 106 may be repeated to form the layer 202 to the desired thickness. For example, if the desired thickness is substantially thicker than that which is sufficient to effectively remove carbon at 104 and/or remove oxygen at 106, then an iterative deposition process may be most effective. For example, the iterative process at 108 may include repeating 102, 104, and optional 106 in the same order and for the same periods of time to achieve the same carbon content and/or oxygen content at each iteration. Alternatively, 102, 104, and 106 may be repeated in any suitable order to tailor the layer 202 to a desired thickness and/or scaling of carbon content and/or oxygen content. For example, it may be more desirable to have higher oxygen content proximate the surface of substrate 200 for improved adhesion and less at a terminal surface of the layer 202 for a desired resistivity. Other combinations which tailor properties of the layer 202, such as adhesion, resistivity, crystallinity, step coverage, deposition rate or the like between the surface of the substrate 200 and the terminal surface of the layer 202 may be utilized. For example, the carbon content and/or oxygen content can be graded in any suitable manner between the surfaces of the layer 202 to achieve a desired property.

Thus, method 100 may provide a ruthenium-containing film 202 comprising ruthenium, carbon and oxygen. For example, in some embodiments, the ruthenium-containing film may be predominantly ruthenium oxide (RuO₂). Further, the ruthenium-containing film may include at least some carbon to the extent that carbon provides desirable layer properties as discussed above. Alternatively, in some embodiments, the ruthenium-containing film 202 may have substantially all carbon removed at 104 and comprise substantially ruthenium and oxygen. In some embodiments, upon completion of method 100, the ruthenium-containing film may have a high deposition rate (e.g., >about 60 Angstroms/min), low resistivity (e.g., <about 60 μOhm-cm, or in some embodiments, such as after annealing, <about 40 μOhm-cm), good step coverage (e.g., about 95% or greater), and good adhesion on surfaces includes at least one of oxides or nitrides.

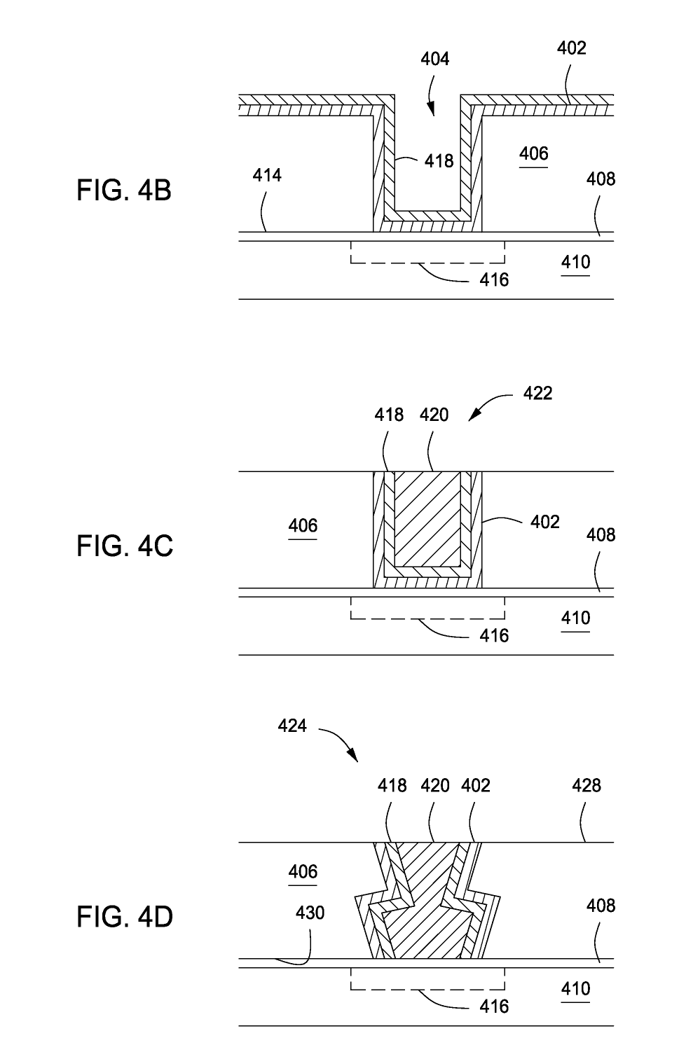

The methods discussed above may be utilized to form a device, for example, such as a pedestal or crown capacitor which may be coupled to one or a source or drain of a transistor to form a DRAM cell. Exemplary capacitor devices are illustrated in FIGS. 4C-D and discussed below.

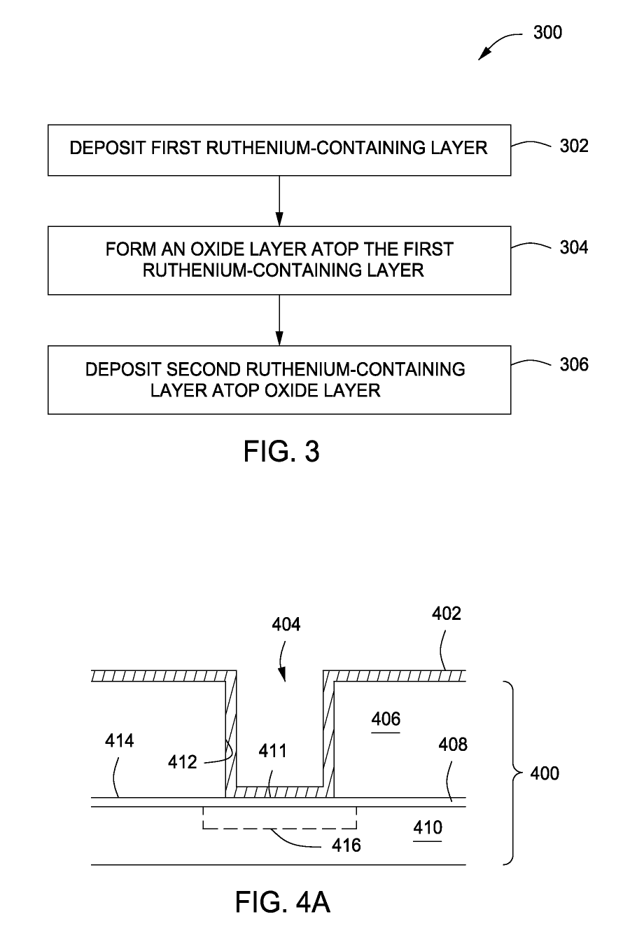

For example, FIG. 3 depicts a flow chart for a method 300 for fabricating a multi-layer structure having one or more ruthenium-containing films in accordance with some embodiments of the present invention. The method 300 is described below with respect to FIGS. 4A-D which depict the stages of fabrication for a multi-layer structure, such as one of the embodiments of a pedestal capacitor depicted in FIGS. 4C-D.

The method 300 begins at 302 by depositing a first ruthenium-containing film 402 on a substrate 400. The first ruthenium-containing film 402 may be substantially similar to the first ruthenium-containing film 202 and formed by any embodiments of the method 100 discussed above. As illustrated in FIG. 4A, the first ruthenium-containing film 402 may be deposited in an opening 404 disposed in the substrate 400. The opening 404 may, for example, be a high aspect ratio feature having a height to width ranging from about 5:1 to about 15:1, or greater than about 15:1. For example, and in some embodiments, the opening 404 may have a circular cross section.

The substrate 400 may include one or more layers. For example, as illustrated in FIG. 4A, the substrate 400 includes a first layer 406, a barrier layer 408 disposed atop the first layer 406, and a second layer 410 disposed atop the barrier layer 408. As shown in FIG. 4A, and in some embodiments, sidewalls 412 of the opening may be formed in and extend through the second layer 410 to an upper surface 414 of the barrier layer 408. A bottom surface 411 of the opening 404 may be formed by the upper surface 414 of the barrier layer 408. The second layer 410 may include one or more dielectric materials, for example, such as ZAZ (ZrO2/AL2O3/ZrO2), or BST (BaₓSr_{y}TiO_{z}). The barrier layer 408 may include one or more of titanium (Ti), titanium nitride (TiN), silicon oxide (SiO₂), or the like.

The first layer 406 may include a conducting or semiconducting material, or alternatively, may be a dielectric material. For example, and in some embodiments, the first layer 406 may be formed from a semiconducting material, such as silicon (Si) and having a doped region 416 (shown by dotted lines in FIGS. 4A-D) disposed therein and below the opening 404. For example, the doped region 416 may be one of a source or drain of a transistor device, such as for use in a DRAM cell. Alternatively, and not shown, the first layer 406 may be formed from a dielectric material and having a conducting portion such as a via, trench or the like disposed therethrough to couple the first ruthenium-containing film 402 to one of a source or drain of a transistor device (not shown) disposed below the first layer 406. For example, the conducting portion may include tungsten (W), copper (Cu), titanium nitride (TiN), aluminum (Al), or the like.

At 304, an oxide layer 418 is formed atop the first ruthenium-containing film 402. For example, the oxide layer 418 may be utilized as a dielectric material between the electrodes of a capacitor device, where the electrodes may be the first ruthenium-containing film 402 and a second ruthenium-containing film 420 discussed below. The oxide layer 418 may include one or more of strontium titanium oxide (SrTiO₃), a multi-layer oxide layer such as ZAZ (ZrO2/AL2O3/ZrO2), or the like. In some embodiments, the oxide layer 418 may be SrTiO₃. The oxide layer 418 may have a thickness ranging from about 10 to about 100 angstroms. In some embodiments, the oxide layer thickness is about 30 to about 50 angstroms.

The oxide layer 418 may be deposited by any suitable method know in the art. For example, the oxide layer 418 may be deposited by thermal oxidation, CVD, ALD, PVD, or the like. Similar to embodiments discussed above for method 100, the oxide layer 418 may be formed in the same CVD process chamber used to form the first ruthenium-containing film 402, or alternatively, a second process chamber configured for an oxidation process may be used.

At 306, the second ruthenium-containing film 420 may be deposited atop the oxide layer 418 as illustrated in FIG. 4C. The second ruthenium-containing film 420, similar to the first ruthenium-containing film 402 may be deposited using any suitable embodiments of the method 100 discussed above for depositing the ruthenium-containing film 202. For example, the second ruthenium-containing film 402 may be deposited by substantially similar embodiments of the method 100 as the first ruthenium-containing film 402. Alternatively, the embodiments of the method 100 used to deposit each of the first and second-ruthenium-containing films 402, 420 may be different. For example, the embodiments for the deposition of each layer 402, 420 may be different due to different step coverage requirements, layer thicknesses, types of layers on which each of the first and second ruthenium-containing films 402, 420 are deposited.

The first and second ruthenium-containing films 402, 420 and the oxide layer 418 may be used to for a device such as a capacitor 422 illustrated in FIG. 4D. For example, in some embodiments, the first and second ruthenium-containing films 402, 420 may be predominantly ruthenium oxide (RuO₂) and the oxide layer 418 may be SrTiO₃. The first and second ruthenium-containing films 402, 420 may include at least some carbon content, for example, about 0.5 atomic percent or less. In some embodiments, the capacitor 422 may have an effective oxide thickness (EOT) of about 5 angstroms or less. Alternative designs of a capacitor are possible. For example, as illustrated in FIG. 4D, a capacitor 424 may be formed in a opening having a non-linear sidewall profile between an upper surface 428 of the second layer 408 and a lower surface 430 of the first layer 406.

Thus, methods for depositing ruthenium-containing films have been disclosed herein. The inventive methods may advantageously allow for a ruthenium-containing film to be deposited having any or all of adequate resistivity, adhesion, deposition rate, or step coverage for device applications. Exemplary device applications may include capacitors having one or more ruthenium-containing films formed by the inventive methods disclosed herein. In some embodiments, the exemplary capacitors may be part of a larger device such as a dynamic random access memory (DRAM) cell.

While the foregoing is directed to embodiments of the present invention, other and further embodiments of the invention may be devised without departing from the basic scope thereof.

1. A method of depositing a ruthenium-containing film on a substrate, comprising:
(a) depositing a ruthenium-containing film on a substrate using a ruthenium-containing precursor, the deposited ruthenium-containing film having carbon incorporated therein; and
(b) exposing the deposited ruthenium-containing film to an oxygen-containing gas to remove at least some of the carbon from the deposited ruthenium-containing film.

2. The method of claim 1, further comprising:
(c) repeating (a)-(b) to deposit the ruthenium-containing film to a desired thickness.

3. The method of claim 2, wherein (a) further comprises:
depositing the ruthenium-containing film to a first thickness.

4. The method of claim 3, wherein the first thickness ranges from about 5 to about 50 angstroms.

5. The method of claim 1, further comprising:
(c) annealing the ruthenium-containing film in a hydrogen-containing gas after (b) to remove at least some oxygen from the ruthenium-containing film.

6. The method of claim 5, further comprising:
(d) repeating (a)-(c) to deposit the ruthenium-containing film to a desired thickness.

7. The method of claim 5, wherein (c) further comprises:
heating the substrate to a temperature of about 200 to about 400 degrees Celsius to anneal the ruthenium-containing film.

8. The method of claim 1, wherein the substrate further comprises:
an upper surface to deposit the ruthenium-containing film thereon, the upper surface including at least one of an oxide or a nitride.

9. The method of claim 8, wherein the upper surface comprises at least one of silicon oxide (SiO₂), silicon nitride (Si₃N₄), strontium titanium oxide (SrTiO₃), or titanium nitride (TiN).

10. The method of claim 1, wherein the ruthenium-containing precursor includes at least one of dimethyl-butadienyl-ruthenium, cyclohexadine-Ru-tricarbonyl, butadiene-Ru-tricarbonyl, dimethyl butadiene-Ru-tricarbonyl, or modified dienes with ruthenium tricarbonyl.

11. The method of claim 1, wherein (b) further comprises:
exposing the deposited ruthenium-containing film to the oxygen-containing gas for a period ranging from about 5 to about 60 seconds.

12. The method of claim 1, wherein the oxygen-containing gas is at least one of oxygen (O₂), water vapor (H₂O), or hydrogen peroxide (H₂O₂).

13. The method of claim 1, wherein the amount of carbon included in the deposited ruthenium-containing film in (a) is at about 2 to about 30 atomic percent.

14. The method of claim 1, wherein an amount of oxygen included in the oxygen-containing gas exposed deposited ruthenium-containing film at the conclusion of (b) is at about 1 to about 15 atomic percent.

15. The method of claim 1, wherein the ruthenium-containing film is a first ruthenium-containing film, and further comprising:
(c) depositing an oxide layer atop the first ruthenium-containing film after (b); and
(d) depositing a second ruthenium-containing film atop the oxide layer as described in (a)-(b).

16. The method of claim 15, further comprising:
(e) repeating (a) and (b) to deposit the first ruthenium-containing film to a first desired thickness; and
(f) repeating (a) and (b) to deposit the second ruthenium-containing film to a second desired thickness.

17. The method of claim 16, wherein (b) further comprises:
(c) annealing the ruthenium-containing film in a hydrogen-containing gas after (b) to remove at least some oxygen from the ruthenium-containing film.

18. The method of claim 15, wherein the first and second ruthenium-containing films comprise oxygen.

19. The method of claim 15, wherein the oxide layer comprises one or more of strontium titanium oxide (SrTiO₃) or a multi-layer oxide layer comprising ZAZ (ZrO2/AL2O3/ZrO2).

20. The method of claim 15, wherein the first and second ruthenium-containing films and the oxide layer form a capacitor and wherein the capacitor is coupled to one of a source or drain of a transistor device via the substrate.
